(19) United States
(12) Patent Application Publication
(10) Pub. No.: US 2011/0058076 A1
(43) Pub. Date: Mar. 10, 2011

(54) SOLID STATE IMAGING DEVICE AND METHOD FOR MANUFACTURING THE SAME

(76) Inventor: Hiroshi TANAKA, Kyoto (JP)

(21) Appl. No.: 12/822,757

(22) Filed: Jun. 24, 2010

(30) Foreign Application Priority Data
Sep. 4, 2009 (JP) 2009-205038

(51) Int. Cl. H04N 5/335; H01L 31/18

(52) U.S. Cl. 348/294; 438/72; 348/E05.091; 257/E31.122

(57) ABSTRACT

A solid state imaging device includes: a light receiving portion and a transfer channel formed in a semiconductor substrate; a transfer electrode formed on the transfer channel; an anti-reflection film formed on the light receiving portion; and a light shielding film which covers the transfer electrode, and is in contact with a side surface of the anti-reflection film. An upper surface of the light shielding film at a contact between the light shielding film and a side surface of the anti-reflection film is located below an upper surface of the light shielding film on the transfer electrode.

### CROSS-REFERENCE TO RELATED APPLICATION

This application claims priority to Japanese Patent Application No. 2009-205038 filed on Sep. 4, 2009, the disclosure of which including the specification, the drawings, and the claims is hereby incorporated by reference in its entirety.

### BACKGROUND

The present disclosure relates to a solid state imaging device, and a method for manufacturing the same, particularly to a solid state imaging device having a light shielding film and an anti-reflection film, and a method for manufacturing the same.

In recent years, solid state imaging elements having higher resolution and a higher number of pixels have been demanded, and manufacturers have been pursuing size reduction of cells. Simultaneously, high sensitivity and low smear comparable to those of conventional solid state imaging devices have been demanded. For these purposes, a method for alleviating reduction of an amount of incident light, and increase of smear due to the size reduction of the cells have been considered. For example, a method for forming a light shielding film has been known, in which an anti-reflection film and a planarization film are formed on a light receiving portion, a light shielding material is laminated thereon, and the laminated light shielding material is polished to expose the planarization film, thereby forming a light shielding film (see, e.g., Japanese Patent Publication No. 2004-140309). The anti-reflection film and the light shielding film formed by this method allow provision of a low-reflection, anti-reflection film on the entire surface of the light receiving portion, thereby increasing the amount of incident light. Further, a semiconductor substrate would not be damaged by etching because the light shielding film is not etched, and therefore, an insulating film formed below the light shielding film can be thinned. This allows reduction of a distance between a lower surface of the light shielding film and the semiconductor substrate, thereby reducing light which enters a transfer channel obliquely, and causes the smear.

### SUMMARY

However, the conventional solid state imaging device has the following disadvantages. In the conventional solid state imaging device, a side surface of the light shielding film is in contact with a side surface of the anti-reflection film, and a distance between a lower surface of the light shielding film and the substrate is small. Therefore, light entering the transfer channel can be reduced. However, since the side surface of the light shielding film is almost perpendicular, light obliquely entering the anti-reflection film is blocked by the light shielding film, thereby causing so-called vignetting.

The present disclosure is intended to overcome the disadvantages described above to reduce smear, and to provide a solid state imaging device in which vignetting of incident light by a light shielding film is reduced.

For the above-described purposes, the present disclosure is directed to a solid state imaging device, wherein a light shielding film is in contact with a side surface of an anti-reflection film, and height of the light shielding film is equal to, or smaller than height of the anti-reflection film at a contact between the light shielding film and the side surface of the anti-reflection film.

Specifically, the disclosed solid state imaging device includes: a light receiving portion and a transfer channel formed in a semiconductor substrate; a transfer electrode formed on the transfer channel; an anti-reflection film formed on the light receiving portion; and a light shielding film which covers the transfer electrode, and is in contact with a side surface of the anti-reflection film, wherein an upper surface of the light shielding film at a contact between the light shielding film and the side surface of the anti-reflection film is located below an upper surface of the light shielding film on the transfer electrode.

In the disclosed solid state imaging device, open space where the light shielding film is not formed is provided obliquely above the anti-reflection film. Therefore, light obliquely entering the anti-reflection film is not blocked by an upper end of the light shielding film, and a range of the light entering the anti-reflection film can be increased, i.e., so-called vignetting can be reduced. Further, since the light shielding film is in contact with the side surface of the anti-reflection film, light traveling in the oblique direction is less likely to enter the transfer channel. In addition, an opening formed in the light shielding film is wholly constituted as a low-reflection region, thereby increasing the amount of incident light.

A method for manufacturing the disclosed solid state imaging device includes: forming a light receiving portion and a transfer channel in a semiconductor substrate; forming a first insulating film on the entire surface of the semiconductor substrate; forming a transfer electrode on the transfer channel after the formation of the first insulating film; forming a second insulating film on the entire surface of the semiconductor substrate to cover the transfer electrode; forming an anti-reflection film on the light receiving portion after the formation of the second insulating film; forming a light shielding film material on the entire surface of the semiconductor substrate after the formation of the anti-reflection film; and forming a light shielding film which covers the transfer electrode, and is in contact with a side surface of the anti-reflection film by selectively removing a portion of the light shielding film material formed on the anti-reflection film, wherein in the formation of the light shielding film, an upper surface of the light shielding film at a contact between the light shielding film and the side surface of the anti-reflection film is located below an upper surface of the light shielding film on the transfer electrode.

The disclosed method for manufacturing the solid state imaging device allows forming the light shielding film to be in contact with the side surface of the anti-reflection film. This makes it possible to reduce an amount of light entering the transfer channel, and to reduce the smear. Further, since the upper surface of the light shielding film at the contact between the light shielding film and the side surface of the anti-reflection film is located below the upper surface of the light shielding film on the transfer electrode, so-called vignetting can be reduced, thereby increasing the amount of incident light.

### BRIEF DESCRIPTION OF THE DRAWINGS

FIGS. 1(a) is a plan view illustrating a solid state imaging device of an embodiment, and FIG. 1(b) is a cross-sectional view taken along the line Ib-Ib in FIG. 1(a).

FIG. 2 is a cross-sectional view illustrating an alternative example of the solid state imaging device of the embodiment.

FIGS. 3(a) to 3(d) are cross-sectional views sequentially illustrating steps for manufacturing the solid state imaging device of the embodiment.

FIG. 4 is an enlarged cross-sectional view illustrating one of the steps for manufacturing the solid state imaging device of the embodiment.

FIG. 5 is a cross-sectional view illustrating an alternative example of the solid state imaging device of the embodiment.

FIGS. 6(a) to 6(c) are cross-sectional views sequentially illustrating steps for manufacturing the alternative example of the solid state imaging device of the embodiment.

FIG. 7 is a cross-sectional view illustrating an alternative example of the solid state imaging device of the embodiment.

FIG. 8 is a cross-sectional view illustrating an alternative example of the solid state imaging device of the embodiment.

FIGS. 9(a) to 9(c) are cross-sectional views illustrating steps for manufacturing the alternative example of the solid state imaging device of the embodiment.

FIG. 10 is a plan view illustrating an alternative example of the solid state imaging device of the embodiment.

FIG. 11 is a plan view illustrating an alternative example of the solid state imaging device of the embodiment.

### DETAILED DESCRIPTION

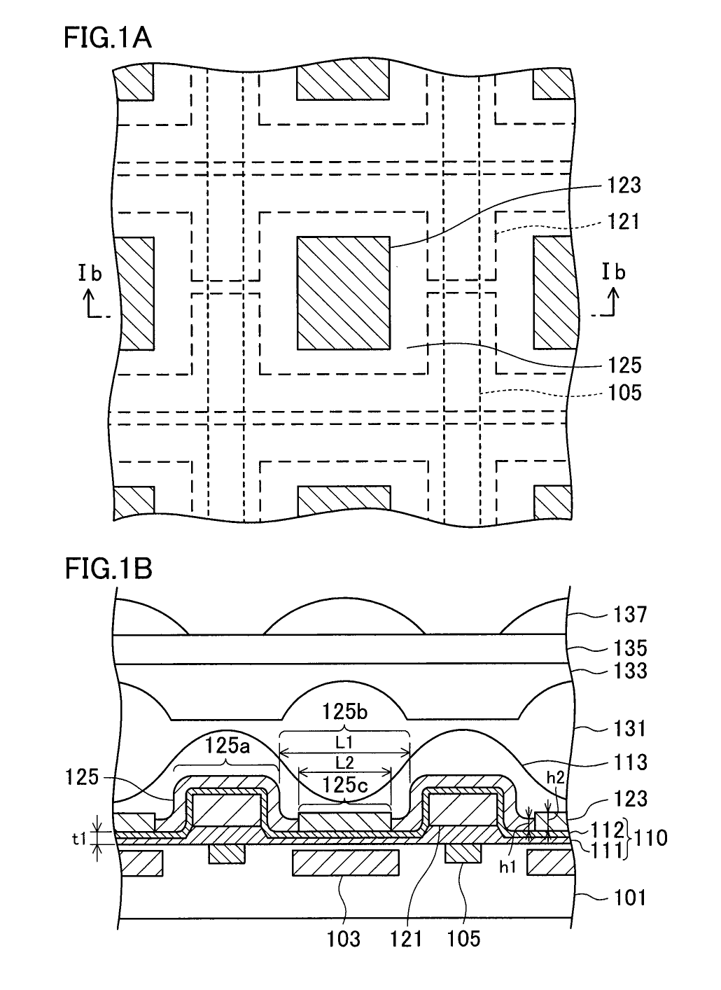

FIGS. 1(a) is a plan view illustrating a solid state imaging device of an embodiment, and FIG. 1(b) is a cross-sectional view taken along the line Ib-Ib in FIG. 1(a). In FIG. 1(a), layers above an upper interlayer insulating film 113 are not shown. As shown in FIGS. 1(a) and 1(b), light receiving portions 103, which are photodiodes, are formed in a matrix pattern in a semiconductor substrate 101 made of silicon (Si) etc. Transfer channels 105 extending in a column direction are formed between the light receiving portions 103. Transfer electrodes 121 are formed on the transfer channels 105 with a first insulating film 111, which is part of a lower interlayer insulating film 110, interposed therebetween. The transfer electrodes 121 extend in a line direction not to overlap with the light receiving portions 103. An upper surface and a side surface of each of the transfer electrodes 121 are covered with a second insulating film 112, which is part of the lower interlayer insulating film 110. The first insulating film 111 and the second insulating film 112 are in contact with each other on the light receiving portions 103, and anti-reflection films 123 are formed in a matrix pattern on the light receiving portions 103 with the first insulating film 111 and the second insulating film 112 interposed therebetween. Upper surfaces of the anti-reflection films 123 are located below upper surfaces of the transfer electrodes 121.

A light shielding film 125 is formed on the second insulating film 112. The light shielding film 125 is formed to cover the side surface and the upper surface of each of the transfer electrodes 121, and includes a protruding portion 125a on each of the transfer electrodes 121, and a recessed portion 125b on the periphery of the transfer electrodes 121. The recessed portion 125b includes an opening 125c in which the anti-reflection film 123 is exposed. The opening 125c is filled with the anti-reflection film 123, and the light shielding film 125 and a side surface of the anti-reflection film 123 are in contact with each other.

An upper interlayer insulating film 113 is formed on the light shielding film 125 and the anti-reflection film 123. The upper interlayer insulating film 113 includes a protruding portion formed on each of the transfer electrodes 121, and a recessed portion formed on each of the anti-reflection films 123. Intralayer lenses 131 are formed on the upper interlayer insulating film 113, and a planarization layer 133 is formed on the intralayer lenses 131. A color filter layer 135, and microlenses 137 are formed on the planarization layer 133.

Incident light collected by the microlens 137 and the intralayer lens 131 which are convex lenses passes through the opening 125c formed in the light shielding film 125 to enter the light receiving portion 103, and is converted to a signal charge. In a general solid state imaging device, the light shielding film and the anti-reflection film are arranged to have a distance of 100 nm or larger therebetween. Therefore, the anti-reflection film is formed to cover only about 60% of an area of the opening. In contrast, in the solid state imaging device of the present embodiment, the light shielding film 125 is in contact with the side surface of the anti-reflection film 123. Thus, the area of the opening 125c is equal to the area of the anti-reflection film 123, i.e., the anti-reflection film 123 is formed to cover 100% of the area of the opening 125c. Therefore, light entering the opening 125c can completely be admitted into the anti-reflection film 123 having an anti-reflection effect, thereby reducing loss of light by the reflection.

In the solid state imaging device of the present embodiment, height h1 of the light shielding film 125 is not larger than height h2 of the anti-reflection film 123 at the contact between the light shielding film 125 and the side surface of the anti-reflection film 123. Specifically, an upper surface of the light shielding film 125 is located below an upper surface of the anti-reflection film 123 at the contact between the light shielding film 125 and the side surface of the anti-reflection film 123. Thus, sidewalls of the recessed portion 125b are separated from the side surfaces of the anti-reflection film 123, i.e., open space where the light shielding film 125 is not formed is provided obliquely above the anti-reflection film 123. In other words, planar dimension LI of an upper end of the recessed portion 125b of the light shielding film 125 is larger than planar dimension L2 of the anti-reflection film 123, i.e., of the opening 125c. Thus, a tangent passing an upper end of the anti-reflection film 123 and the sidewall of the recessed portion 125b forms an angle smaller than 90° with a principle surface of the semiconductor substrate 101. This can reduce vignetting, which is a phenomenon in which light obliquely entering the light receiving portion is blocked by an upper end of the light shielding film 125.

In the solid state imaging device of the present embodiment, the light shielding film 125 and the side surface of the anti-reflection film 123 are in contact with each other. Thus, at the contact between the light shielding film 125 and the side surface of the anti-reflection film 123, a distance between the light shielding film 125 and the semiconductor substrate 101 can advantageously be reduced. For providing a distance between the light shielding film and the anti-reflection film, the light shielding film on the periphery of the anti-reflection film has to be removed. In this case, an insulating film formed under the light shielding film has to be thickened for the purpose of protecting the surface of the semiconductor substrate from damage caused by etching the light shielding film. In the solid state imaging device of the present embodiment, however, the light shielding film 125 and the side surface of the anti-reflection film 123 are in contact with each other. Thus, the light shielding film 125 is not etched, and the semiconductor substrate 101 is not damaged by etching. Therefore, the first insulating film 111 and the second insulating film 112 near the contact between the light shielding film 125 and the anti-reflection film 123 can be thinned down. This can reduce a distance t1 between the light shielding film 125 and the semiconductor substrate 101, and can reduce light entering the transfer channel 105 by passing below the light shielding film 125. This can further reduce the smear.

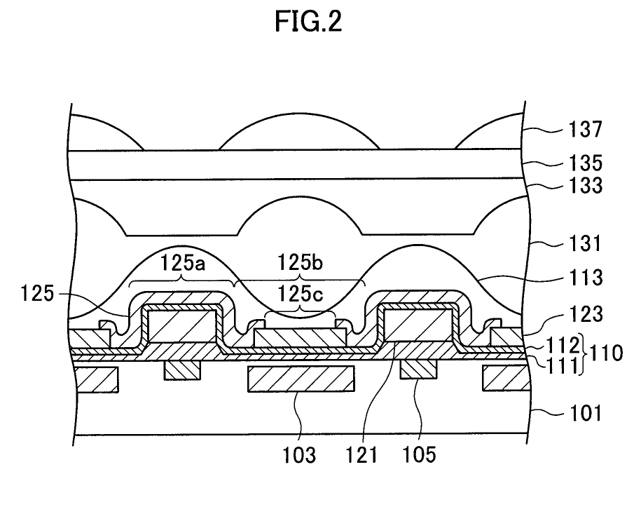

FIGS. 1(a) and 1(b) show an example in which the upper surface of the light shielding film 125 is located below the upper surface of the anti-reflection film 123 at the contact between the light shielding film 125 and the side surface of the anti-reflection film 123. However, as long as the upper surface of the light shielding film 125 at the contact between the light shielding film 125 and the anti-reflection film 123 is located below the upper surface of the light shielding film on the transfer electrode 121, the sidewalls of the recessed portion 125b can be separated from the side surfaces of the anti-reflection film 123. The light shielding film 125 is preferably not formed on the upper surface of the anti-reflection film 123. However, as shown in FIG. 2, the light shielding film 125 may cover an upper surface of a peripheral portion of the anti-reflection film 123.

A method for manufacturing the solid state imaging device of the present embodiment will be described below.

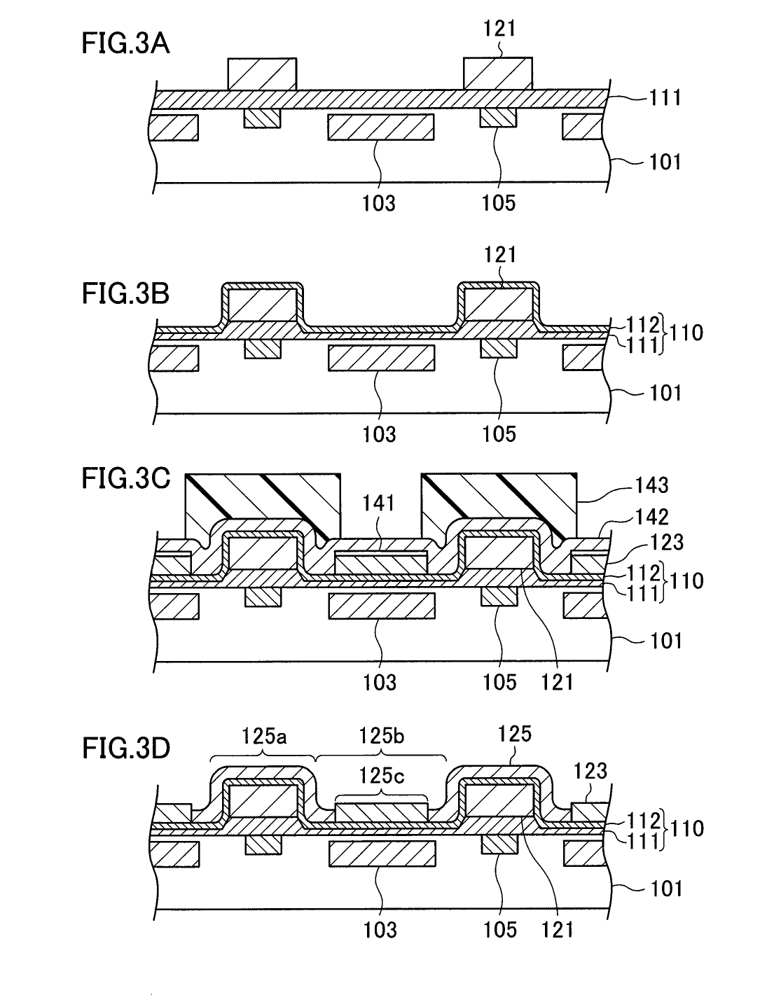

First, as shown in FIG. 3(a), a plurality of light receiving portions 103 arranged in a matrix pattern, and a plurality of transfer channels 105 extending in a column direction are formed in a semiconductor substrate 101, such as a Si substrate etc. Then, a first insulating film 111 made of a SiO₂ film etc., is formed on the semiconductor substrate 101 by CVD (chemical vapor deposition) etc. Then, transfer electrodes 121 extending in a line direction are formed not to overlap with the light receiving portions 103.

As shown in FIG. 3(b), the first insulating film 111 is selectively etched using the transfer electrodes 121 as a mask. Thus, a portion of the first insulating film 111 on which the transfer electrode 121 is not formed is made thinner than a portion of the first insulating film 111 on which the transfer electrode 121 is formed. If wet etching is employed to etch the first insulating film 111, the semiconductor substrate 101 would hardly be damaged. Then, a second insulating film 112 is formed on the semiconductor substrate 101 by CVD etc. The thickness of the second insulating film 112 is determined to keep a dielectric breakdown voltage required between the transfer electrode 121 and the light shielding film 125. For example, when a dielectric breakdown voltage of 30 V is required between the transfer electrode 121 and the light shielding film 125, a 30 nm thick SiO₂ film having a dielectric breakdown voltage of 10 MV/cm may be formed by CVD as the second insulating film 112. In this case, the sum of the thicknesses of the first insulating film 111 and the second insulating film 112 on the light receiving portion 103 may be about 40 nm. Then, as shown in FIG. 3(c), an anti-reflection film 123 and an etch stop layer 141 are selectively formed on the light receiving portions 103. The anti-reflection film 123 may be a silicon nitride film etc., formed by CVD. The etch stop layer 141 may be a silicon oxide film etc. Then, a light shielding film material 142 is provided on the semiconductor substrate 101. The light shielding film material 142 may be aluminum, refractory metal, etc. The light shielding film material 142 is provided to completely fill recesses between the transfer electrodes 121 and the anti-reflection films 123. Then, a resist mask 143 having openings on the anti-reflection films 123 is formed.

Then, as shown in FIG. 3(d), exposed portions of the light shielding film material 142 are removed by dry etching using the resist mask 143, and the etch stop layer 141 and the resist mask 143 are removed. The etch stop layer 141 may not be removed. In this case, the remaining etch stop layer 141 becomes part of the upper interlayer insulating film 113.

In the method described above, the light shielding film material 142 formed on the anti-reflection film 123 can reliably be removed. The light shielding film material 142 formed on the anti-reflection film 123 is preferably removed completely. However, the light shielding film 142 may be left on a peripheral portion of the anti-reflection film 123.

Even if the resist mask 143 is misaligned, a portion of the light shielding film material 142 formed between the transfer electrodes 121 and the anti-reflection films 123 is not completely etched, but remains there because the portion is thicker than the other portion of the light shielding film material 142. Thus, the light shielding film 125 and the anti-reflection film 123 would not form a gap therebetween which exposes the lower interlayer insulating film 110, and the light shielding film 125 is in contact with the side surface of the anti-reflection film 123. Accordingly, the light would never enter through a gap between the light shielding film 125 and the anti-reflection film 123, thereby reducing the smear. At the contact between the light shielding film 125 and the side surface of the anti-reflection film 123, the height of the light shielding film 125 is not larger than the height of the anti-reflection film 123. Thus, the side surface of the light shielding film 125 is separated from the side surface of the anti-reflection film, thereby providing open space where the light shielding film 125 is not formed obliquely above the anti-reflection film 123. Therefore, light traveling in the oblique direction can enter the anti-reflection film 123 without being blocked by an upper end of the light shielding film 125. This can reduce vignetting, and can alleviate reduction in amount of the incident light.

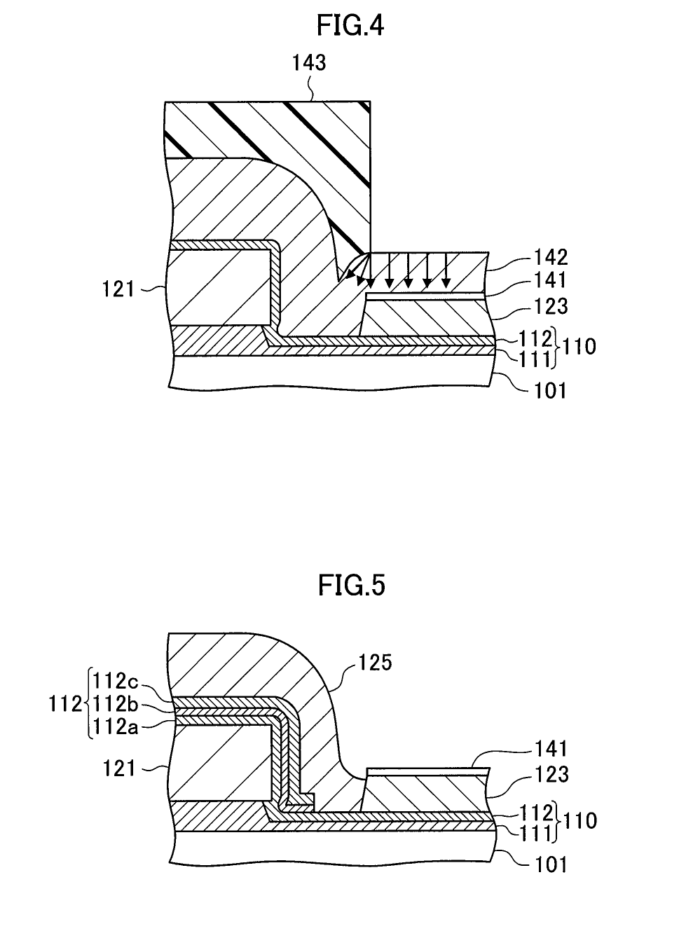

In this case, the resist mask 143 may be formed to overlap with the anti-reflection film 123 by 20 nm to 30 nm as shown in FIG. 4. In etching the light shielding film material 142, etching proceeds also in the lateral direction. Therefore, the light shielding film material 142 on the anti-reflection film 123 can completely be removed, and the side surface of the anti-reflection film 123 and the light shielding film 125 can easily be brought into contact. However, the resist mask 143 may not always overlap with the anti-reflection film 123. Further, in this example, height hl of the light shielding film 125 is smaller than height h2 of the anti-reflection film 123 at the contact between the light shielding film 125 and the side surface of the anti-reflection film 123. However, the height h1 of the light shielding film 125 may be equal to the height h2 of the anti-reflection film 123. Alternatively, the height h1 may be larger than the height h2. However, in general, the light shielding film material 142 is etched until the entire upper surface of the anti-reflection film 123 is fully exposed. Therefore, the height of the light shielding film 125 is generally smaller than the height of the anti-reflection film 123 at the contact between the light shielding film 125 and the side surface of the anti-reflection film 123. Thus, an upper end of the side surface of the anti-reflection film 123 is uncovered with the light shielding film 125. This would not cause any disadvantages.

After the etch stop layer 141 and the resist mask 143 are removed, an upper interlayer insulating film 113, intralayer lenses 131, a planarization layer 133, a color filter layer 135, microlenses 137, etc., are formed, although not shown.

In view of reducing the smear, a distance t1 between the light shielding film 125 and the semiconductor substrate 101 is preferably small at the contact between the light shielding film 125 and the side surface of the anti-reflection film 123. For this reason, the first insulating film 111 is thinned except for a portion thereof on which the transfer electrode 121 is formed. However, the second insulating film 112 functions to insulate the transfer electrodes 121 and the light shielding film 125, and has to have a certain thickness. To reduce the distance between the light shielding film 125 and the semiconductor substrate 101 to a further extent, a portion of the second insulating film 112 covering the side surfaces and the upper surface of the transfer electrodes 121 may be thickened, and a portion of the second insulating film 112 under the anti-reflection film 123 may be thinned. In this manner, thickness t1 of the first insulating film 111 and the second insulating film 112 under the anti-reflection film 123 can be reduced to a further extent, while ensuring a required dielectric breakdown voltage.

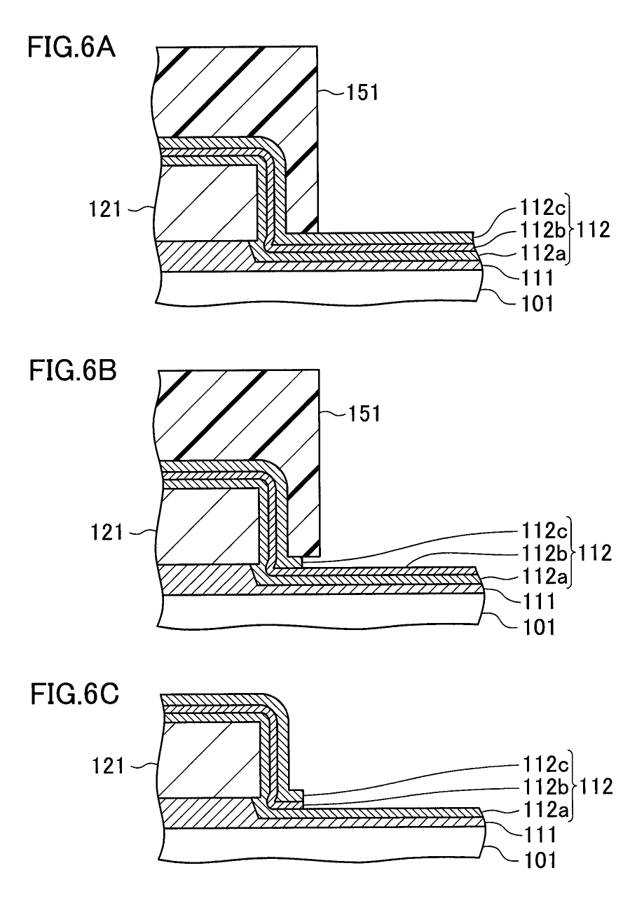

For example, as shown in FIG. 5, the second insulating film 112 may be constituted of a laminate of a first silicon oxide film 112a, a silicon nitride film 112b, and a second silicon oxide film 112c, and the second silicon oxide film 112c and the silicon nitride film 112b may be removed from the periphery of the anti-reflection film 123. Due to the difference in etch rate of the silicon oxide film and the silicon nitride film, the second silicon oxide film 112c and the silicon nitride film 112b can easily be removed, with the first silicon oxide film 112a kept remained. Specifically, as shown in FIG. 6(a), the first silicon oxide film 112a, the silicon nitride film 112b, and the second silicon oxide film 112c are formed sequentially on the semiconductor substrate 101, and then a resist mask 151 which does not cover a region for forming the anti-reflection film 123 is formed. Then, an exposed portion of the second silicon oxide film 112c is removed as shown in FIG. 6(b). Further, an exposed portion of the silicon nitride film 112b is removed as shown in FIG. 6(c). If the silicon nitride film 112b is removed using hot concentrated phosphoric acid etc., only the silicon nitride film 112b can be removed without etching the first silicon oxide film 112a.

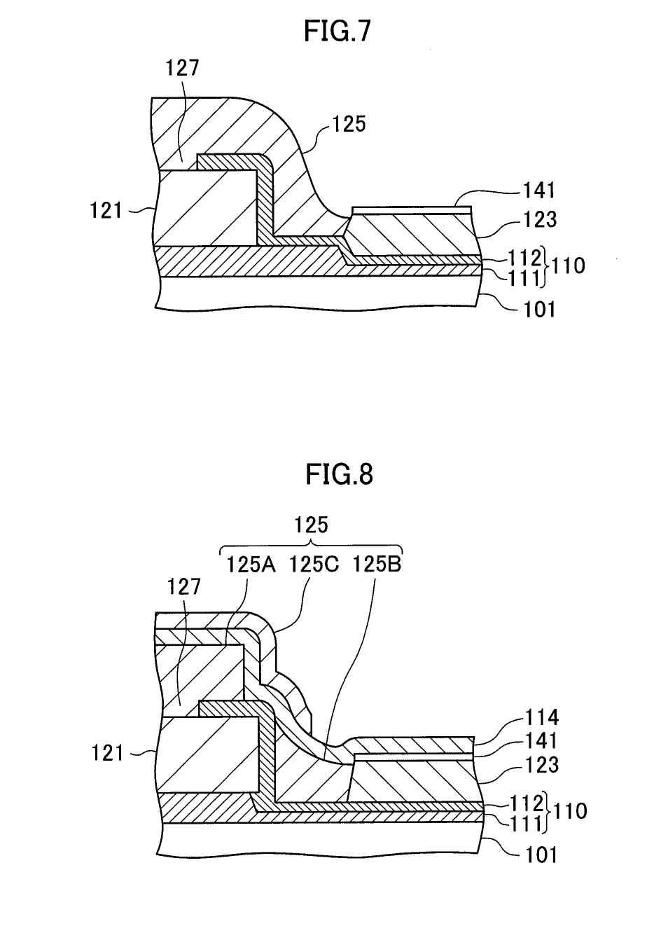

As shown in FIG. 7, the light shielding film 125 and the transfer electrode 121 are connected through a contact 127, and the light shielding film 125 may be used as a shunt wire. In this case, the lower interlayer insulating film 110 between the light shielding film 125 and the semiconductor substrate 101 has to be thickened to ensure a dielectric breakdown voltage between the light shielding film 125 and the semiconductor substrate 101. For this reason, the first insulating film 111 under the light shielding film 125 is not thinned, but is kept thick. However, the first insulating film 111 may be thinned to such a degree that the dielectric breakdown voltage between the light shielding film 125 and the semiconductor substrate 101 can be ensured.

With the lower interlayer insulating film 110 under the anti-reflection film 123 made thin, the effect of the anti-reflection film 123 is enhanced. Therefore, the first insulating film 111 under the anti-reflection film 123 is preferably thinned. If the sum of the thicknesses of the first and second insulating films 111 and 112 under the anti-reflection film 123 is in the range of 10 nm to 20 nm, the effect of the anti-reflection film 123 can further be enhanced. In the case where the light shielding film 125 is used as a shunt wire, the second insulating film 112 may be constituted of a laminate of layers.

Even when the light shielding film 125 is used as the shunt wire, the first insulating film 111 under the light shielding film 125 can be thinned, and the smear can be reduced to a further extent by employing the configuration shown in FIG. 8. Specifically, a first light shielding film 125A connected to the transfer electrode 121 through the contact 127 is formed on the transfer electrode 121. A second shielding film 125B is formed to fill a recess between the transfer electrode 121 and the anti-reflection film 123. A third light shielding film 125C is formed to overlap with both the first light shielding film 125A and a second light shielding film 125B. The first light shielding film 125A, the second light shielding film 125B, and the third light shielding film 125C are insulated from each other by a third insulating film 114. With this configuration, a voltage is not applied to the second light shielding film 125B. Therefore, an insulating film between the second light shielding film 125B and the semiconductor substrate 101 can be thinned. Further, since the third light shielding film 125C is formed to overlap with both the first light shielding film 125A and the second light shielding film 125B, light would not pass between the first light shielding film 125A and the second light shielding film 125B to enter the transfer channel 105.

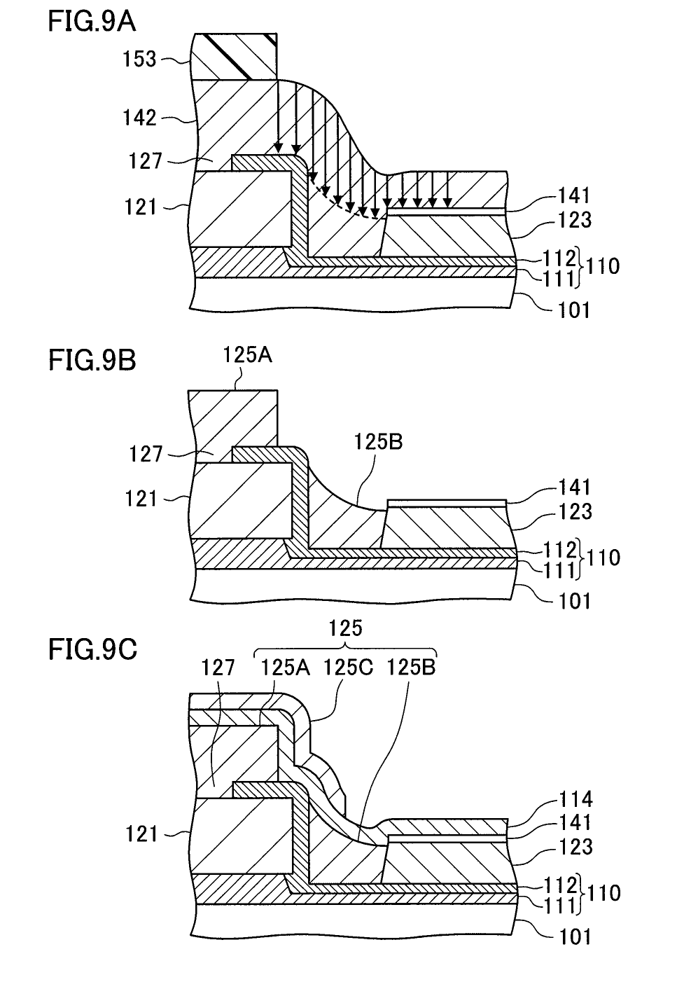

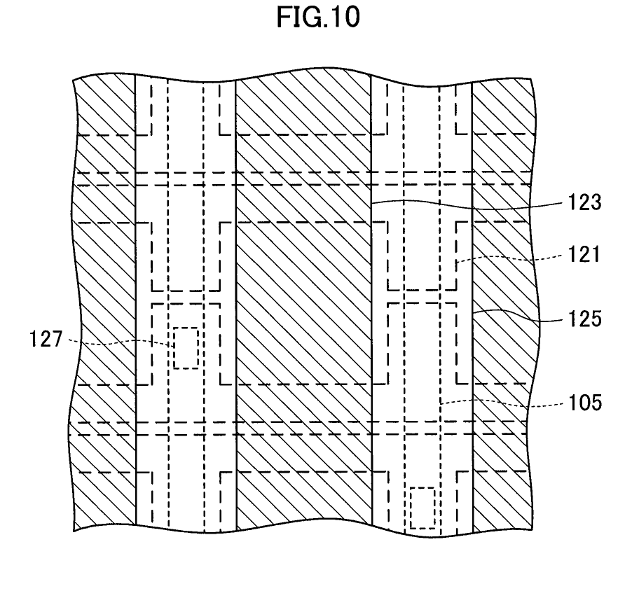

The first light shielding film 125A, the second light shielding film 125B, and the third light shielding film 125C may be formed in the following manner. As shown in FIG. 9(a), after the light shielding film material 142 is formed, a resist mask 153 covering the transfer electrodes 121 is formed. Planar dimension of the resist mask 153 is preferably smaller than planar dimension of the transfer electrode 121. Then, as shown in FIG. 9(b), the light shielding film material 142 is etched until the etch stop layer 141 and the second insulating film 112 are partially exposed, thereby forming a first light shielding film 125A and a second light shielding film 125B. Then, as shown in FIG. 9(c), a third insulating film 114 is formed on the semiconductor substrate 101. Thereafter, a third light shielding film 125C is formed on the third insulating film 114, and a portion of the third light shielding film 125C on the anti-reflection film 123 is selectively removed. In the case where the light shielding film is constituted of the first, second, and third light shielding films, the second insulating film 112 may be constituted of a laminate of layers.

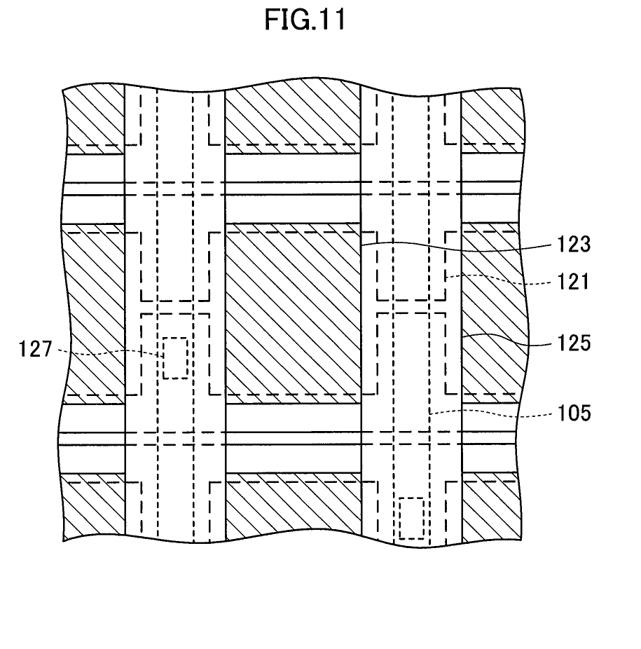

When the light shielding film 125 is used as the shunt wire, the light shielding film 125 is not formed between the light receiving portions 103 adjacent to each other in the column direction. Therefore, as shown in FIG. 10, the anti-reflection film 123 may be increased in length in the column direction to overlap with the transfer electrodes 121. Further, as shown in FIG. 11, the anti-reflection films 123 adjacent to each other in the column direction may be integrated.

In FIGS. 5, 7, 8, 10, and 11, the light receiving portions 103, the transfer channels 105, and layers above the upper interlayer insulating film 113 are not shown.

According to the disclosed solid state imaging device and the method for manufacturing the same, the smear can be reduced, and vignetting of incident light caused by the light shielding film can be reduced. The present disclosure is particularly useful for solid state imaging devices including multiple pixels, and for a method for manufacturing the same.

The term “on” used in the specification and claims does not indicate that a first layer “on” a second layer is directly on, and in immediate contact with the second layer unless otherwise stated. A third layer or other structure may be present between the first layer and the second layer on the first layer.

Although the invention has been described with reference to specific embodiments, the description is intended to be illustrative of the invention, and is not intended to be limiting.

Various modifications and applications may occur to those skilled in the art without departing from the true spirit of the invention as defined in the appended claims.

What is claimed is:

1. A solid state imaging device comprising:
a light receiving portion and a transfer channel formed in a semiconductor substrate;
a transfer electrode formed on the transfer channel;
an anti-reflection film formed on the light receiving portion; and
a light shielding film which covers the transfer electrode, and is in contact with a side surface of the anti-reflection film, wherein
an upper surface of the light shielding film at a contact between the light shielding film and the side surface of the anti-reflection film is located below an upper surface of the light shielding film on the transfer electrode.

2. The solid state imaging device of claim 1, wherein
the upper surface of the light shielding film at the contact between the light shielding film and the side surface of the anti-reflection film is located below an upper surface of the anti-reflection film.

3. The solid state imaging device of claim 1, wherein
the light shielding film partially covers the upper surface of the anti-reflection film.

4. The solid state imaging device of claim 1, further comprising:
an interlayer insulating film formed on the semiconductor substrate, wherein
the interlayer insulating film includes:
a first insulating film formed between the transfer electrode and the transfer channel, and between the anti-reflection film and the light receiving portion; and
a second insulating film formed between the light shielding film and the transfer electrode, and between the anti-reflection film and the first insulating film, and
a portion of the interlayer insulating film between the anti-reflection film and the light receiving portion is thinner than a portion of the interlayer insulating film between the transfer electrode and the transfer channel.

5. The solid state imaging device of claim 4, wherein
the second insulating film includes a first silicon oxide film, a silicon nitride film, and a second silicon oxide film,
a portion of the interlayer insulating film between the light shielding film and the transfer electrode is constituted of the first silicon oxide film, the silicon nitride film, and the second silicon oxide film, and
the portion of the interlayer insulating film between the anti-reflection film and the light receiving portion is constituted of the first insulating film and the first silicon oxide film.

6. The solid state imaging device of claim 4, wherein
a portion of the interlayer insulating film below the contact between the light shielding film and the side surface of the anti-reflection film is thinner than the portion of the interlayer insulating film between the transfer electrode and the transfer channel.

7. The solid state imaging device of claim 4, wherein
the light shielding film and the transfer electrode are connected through a contact which penetrates the interlayer insulating film, and
a portion of the interlayer insulating film between the light shielding film and the semiconductor substrate is as thick as, or thicker than a portion of the interlayer insulating film between the transfer electrode and the light shielding film.

8. The solid state imaging device of claim 4, wherein
the light shielding film includes:
a first light shielding film which is formed on the transfer electrode, and is connected to the transfer electrode through a contact which penetrates the interlayer insulating film,
a second light shielding film which is insulated from the first light shielding film, and is in contact with the side surface of the anti-reflection film, and
a third light shielding film which is insulated from the first and second light shielding films, and overlaps with both the first light shielding film and the second light shielding film.

9. A method for manufacturing a solid state imaging device comprising:
forming a light receiving portion and a transfer channel in a semiconductor substrate;
forming a first insulating film on the entire surface of the semiconductor substrate;
forming a transfer electrode on the transfer channel after the formation of the first insulating film;
forming a second insulating film on the entire surface of the semiconductor substrate to cover the transfer electrode;
forming an anti-reflection film on the light receiving portion after the formation of the second insulating film;
forming a light shielding film material on the entire surface of the semiconductor substrate after the formation of the anti-reflection film; and
forming a light shielding film which covers the transfer electrode, and is in contact with a side surface of the anti-reflection film by selectively removing a portion of the light shielding film material formed on the anti-reflection film, wherein
in the formation of the light shielding film, an upper surface of the light shielding film at a contact between the light shielding film and the side surface of the anti-reflection film is located below an upper surface of the light shielding film on the transfer electrode.

10. The method for manufacturing the solid state imaging device of claim 9, wherein
in the formation of the light shielding film, the upper surface of the light shielding film at the contact between the light shielding film and the side surface of the anti-reflection film is located below an upper surface of the anti-reflection film.

11. The method for manufacturing the solid state imaging device of claim 9, wherein
in the formation of the light shielding film, the light shielding film is left on a peripheral portion of the anti-reflection film.

12. The method for manufacturing the solid state imaging device of claim 9, further comprising:
thinning a portion of the first insulating film on the periphery of the transfer electrode after the formation of the transfer electrode, and before the formation of the second insulating film.

13. The method for manufacturing the solid state imaging device of claim 9, wherein
in the formation of the second insulating film, a first silicon oxide film, a silicon nitride film, and a second silicon oxide film are sequentially formed on the entire surface of the semiconductor substrate, and then the second silicon oxide film, and the silicon nitride film are selectively removed from a region for forming the anti-reflection film.

14. The method for manufacturing the solid state imaging device of claim 9, wherein
the light shielding film includes a first light shielding film, a second light shielding film, and a third light shielding film,
the formation of the light shielding film includes:
forming the first light shielding film on the transfer electrode, and the second light shielding film which is located between the transfer electrode and the anti-reflection film, and is insulated from the first light shielding film by etching the light shielding film material;
forming a third insulating film covering the first and second light shielding films; and
forming the third light shielding film on the third insulating film to overlap both the first light shielding film and the second light shielding film.
